(19) United States
(12) Patent Application Publication
(10) Pub. No.: US 2010/0259144 A1
(43) Pub. Date: Oct. 14, 2010

(54) DEVICE CASE AND APPARATUS USING SAME

(76) Inventors: JOEBEN BEVIRT, Santa Cruz, CA (US); Kenneth Minn, San Francisco, CA (US)

Correspondence Address: MICHAEL A. GUTH, 2-2905 EAST CLIFF DRIVE, SANTA CRUZ, CA, 95062, US

(21) Appl. No.: 12/610,855

(22) Filed: Nov. 2, 2009

Related U.S. Application Data
(63) Continuation-in-part of application No. 11/895,020, filed on Aug. 22, 2007.
Application No. 11/895,020 is a continuation-in-part of application No. 11/324,994, filed on Jan. 3, 2006.
Application No. 11/324,994 is a continuation-in-part of application No. 11/637,611, filed on Dec. 12, 2006.
Application No. 11/637,611 is a continuation-in-part of application No. 11/324,994, filed on Jan. 3, 2006.

(51) Int. Cl. H05K 5/02; A47B 83/00; F16M 11/04

(52) U.S. Cl. 312/237; 312/223.1

(57) ABSTRACT

A case for an electronic device, such as a cellular telephone. The case may be adapted to be supported by a flexible support apparatus, such as a tripod. The flexible tripod may include ball and socket joint connectors which, when interconnected, form a flexible assembly. The flexible support apparatus allows the user to view the device in a variety of locations with enhanced ease, comfort, and allows for a variety of viewing or use angles.

### CROSS-REFERENCE TO RELATED APPLICATIONS

This application is a continuation in part of U.S. application Ser. No. 11/895,020 to Bevirt et al., filed Aug. 22, 2007, which is a continuation in part of U.S. application Ser. No. 11/637,611 to Bevirt et al., filed Dec. 12, 2006, which is a continuation in part of U.S. patent application Ser. No. 11/324,994 to Bevirt, filed Jan. 3, 2006, which are all hereby incorporated by reference in their entirety.

### BACKGROUND

1. Field of the Invention

The present invention relates to a device case and clip, and a flexible support apparatus, such as a tripod, adapted to support an item mounted in the device case.

2. Description of Related Art

Modern portable electronic devices, such as cellular telephones, may now be used for viewing as well. However, these items are typically small, flat, rectangular objects which may be difficult to place in an appropriate position for hands-free use while viewing. Also, when used as communications devices, they may also suffer from a lack of a practical way to place or hold the device. Such devices may also be enhanced with the use of a protective case which affords impact protection for the device.

The use of a portable electronic device may be enhanced with the use of a tripod or other support structure. Typical tripod assemblies consist of three rigid legs which are splayed out to form a support structure for devices such as cameras. The legs are usually rigid and adapted to provide support off of the ground or other flat surface. Some tripods have some adjustment to leg length which may allow for some deviation from flatness in the surface upon which they are mounted.

Such tripods are limited in the manner in which they support devices such as cameras. What is called for is a mounting apparatus that may function as a tripod and also as a grip mount for the mounting to vertical members. What is also called for is a case for an electronic device which allows the mounting of the electronic device to a support structure such as a tripod.

### SUMMARY

The present invention is directed towards a case for an electronic device, such as a cellular telephone. The case may be adapted to be supported by a flexible support apparatus, such as a tripod. The flexible tripod may include ball and socket joint connectors which, when interconnected, form a flexible assembly. The flexible support apparatus allows the user to view the device in a variety of locations with enhanced ease, comfort, and allows for a variety of viewing or use angles.

### BRIEF DESCRIPTION OF THE DRAWINGS

FIGS. 1A-E illustrate an electronic device according to some embodiments of the present invention.

FIGS. 2A-D illustrate an electronic device mounted to a flexible tripod according to some embodiments of the present invention.

FIGS. 3A-C illustrate a device mount according to some embodiments of the present invention.

FIGS. 4A-B illustrate an electronic device mounted into a device mount according to some embodiments of the present invention.

FIGS. 5A-B illustrate a flexible support structure according to some embodiments of the present invention.

FIGS. 6A-C illustrate an apparatus assembled from an electronic device mounted in a mount attached to a flexible tripod 20.

FIGS. 7A-D illustrate an apparatus assembled from an electronic device with an integral clip mounted onto a flexible tripod according to some embodiments of the present invention.

FIG. 8 is a side view of a flexible leg according to some embodiments of the present invention.

FIG. 9 is an end view of a flexible leg according to some embodiments of the present invention.

FIG. 10 is a cross-sectional view of a flexible leg according to some embodiments of the present invention.

FIGS. 11 and 11A are a side and cross-sectional view of a connector according to some embodiments of the present invention.

FIG. 12 is a side view of a connector according to some embodiments of the present invention.

FIGS. 13 and 13A are a side and cross-sectional view of a connector according to some embodiments of the present invention.

FIG. 14 is a picture of a flexible tripod holding a video player according to some embodiments of the present invention.

FIG. 15 is a picture of a flexible tripod holding a video player according to some embodiments of the present invention.

FIG. 16 is a shaded perspective view of a case according to some embodiments of the present invention.

FIG. 17 is a rear perspective view of a case according to some embodiments of the present invention.

FIG. 18 is a front perspective view of a case according to some embodiments of the present invention.

FIG. 19 is a rear perspective view of a case according to some embodiments of the present invention.

FIG. 20 is a front view of a case and electronic device according to some embodiments of the present invention.

FIG. 21 is a top view of a case and electronic device according to some embodiments of the present invention.

FIG. 22 is a back view of a case and electronic device according to some embodiments of the present invention.

FIG. 23 is a bottom view of a case and electronic device according to some embodiments of the present invention.

FIG. 24 is a side view of a case and electronic device according to some embodiments of the present invention.

FIG. 25 is a perspective view of a case and tripod according to some embodiments of the present invention.

FIG. 26 is a front view of a case and tripod according to some embodiments of the present invention.

FIG. 27 is a side view of a case and tripod according to some embodiments of the present invention.

FIG. 28 is a perspective view of a case, electronic device, and tripod assembly according to some embodiments of the present invention.

FIG. 29 is a rear perspective view of a case, electronic device, and tripod assembly according to some embodiments of the present invention.

FIG. 30 is a sketch of a flexible leg wrapped around an object according to some embodiments of the present invention.

FIG. 31 is a sketch of a flexible leg wrapped around an object according to some embodiments of the present invention.

FIG. 32 is a perspective view of a clip illustrating aspects of clips according to some embodiments of the present invention.

FIG. 33 is a side view of a clip illustrating aspects of clips according to some embodiments of the present invention.

FIG. 34 is a top view of a clip illustrating aspects of clips according to some embodiments of the present invention.

### DETAILED DESCRIPTION

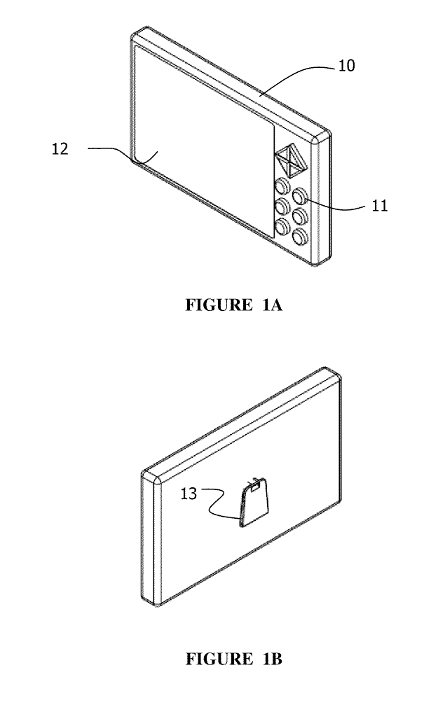

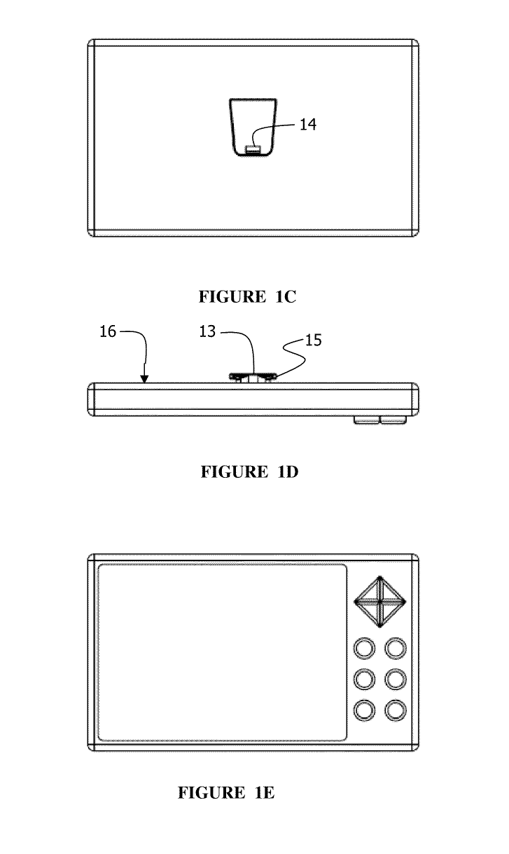

FIGS. 1A-E illustrate an electronic device 10 according to some embodiments of the present invention. In some embodiments, the electronic device is a video player. The electronic device may also be a GPS device, a remote monitor, or other device. The electronic device may have a screen 12 and control features 11.

In some embodiments, the electronic device 10 has a mounting clip 13 mounted to its back surface 16. The mounting clip 13 is adapted to clip into a support structure such as a tripod, or a flexible tripod. The clip 13 may have a recess 14 on its bottom surface adapted to receive a tab from its mating interface. The clip 13 may have rails 15 around some of its bottom edges adapted to mate into the receiver of the support structure. In some embodiments, the clip may be mounted to a different surface or edge of the electronic device 10.

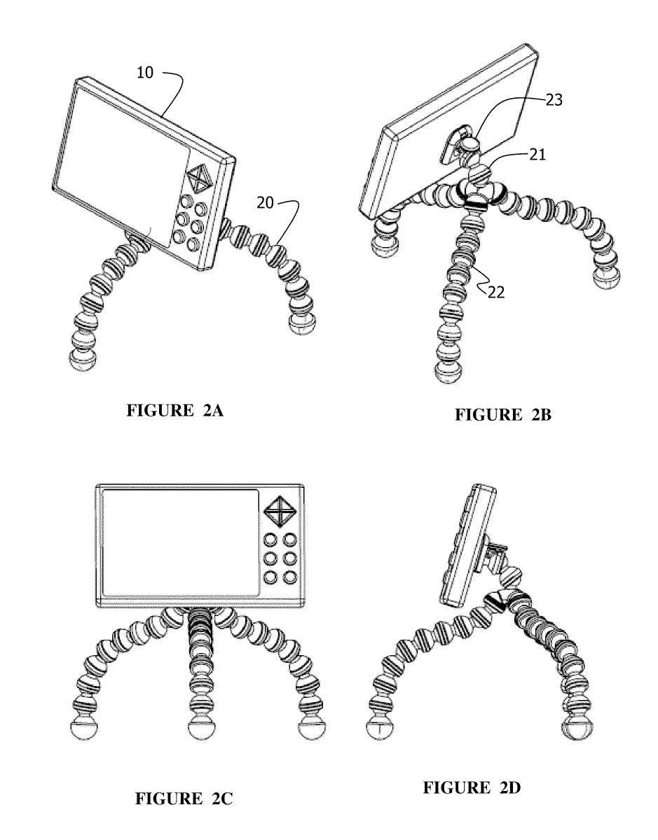

FIGS. 2A-D illustrate an electronic device 10 mounted to a flexible tripod 20 according to some embodiments of the present invention. The electronic device 10 may be attached to the interconnect portion 21 of the tripod. A release button 23 may release the mounting clip from the receiver of the interconnect portion. In some embodiments, the receiver is adapted to receive the clip and to latch a tab into the recess 14 such that although the device 10 may be easily inserted into the receiver, the tab must be pushed to allow for easy removal of the device 10 from the tripod 20.

The use of a flexible support, such as a flexible tripod, gives the distinct advantage of allowing the user to position an electronic device, such as a personal video player, in a convenient position for viewing. For example, the tripod may be placed upon a table, or an airplane seat's foldout tray, for viewing and use. The flexible legs may be used to attach and hang the device in a position where heretofore no such viewing was possible. In the case of other electronic devices, for example a baby monitor, the flexible legs of the tripod may be wrapped around the vertical ribs of a baby's crib, for example.

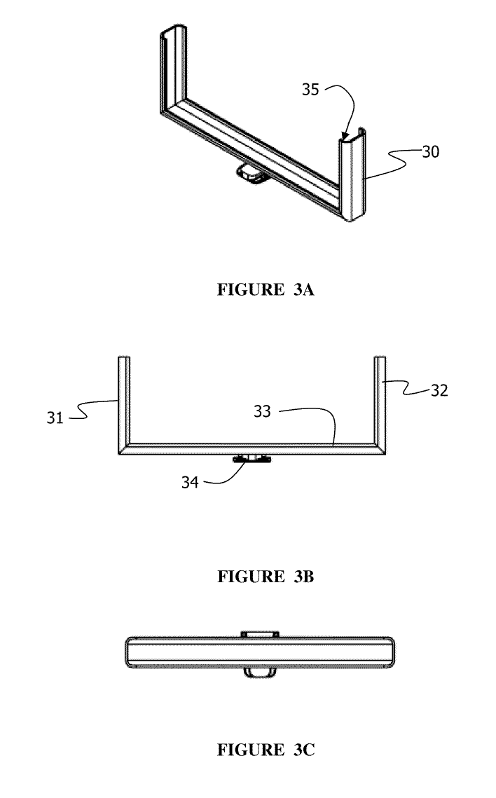

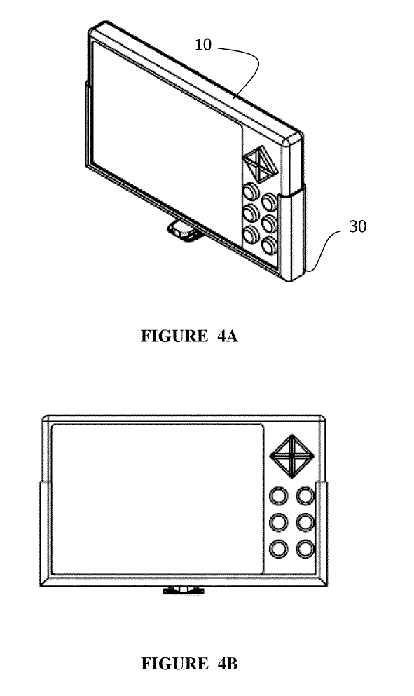

FIGS. 3A-C illustrate a device mount 30 according to some embodiments of the present invention. The device mount 30 is adapted to receive and hold an electronic device, or other device, and to allow for easy attachment and removal to a support structure, such as a flexible tripod. The device mount 30 may have a frame consisting of two side rails 31, 32 and a center rail 33. The rails may have a channel 35 with somewhat flexible yet rigid walls such that a device, such as a personal video player, may be inserted therein and be restrained within the mount to allow for attachment of the mounted device to a support structure such as a flexible tripod. FIGS. 4A-B illustrate an electronic device mounted into a device mount 30 according to some embodiments of the present invention. In some embodiments, the device mount 30 may be adapted for a particular device.

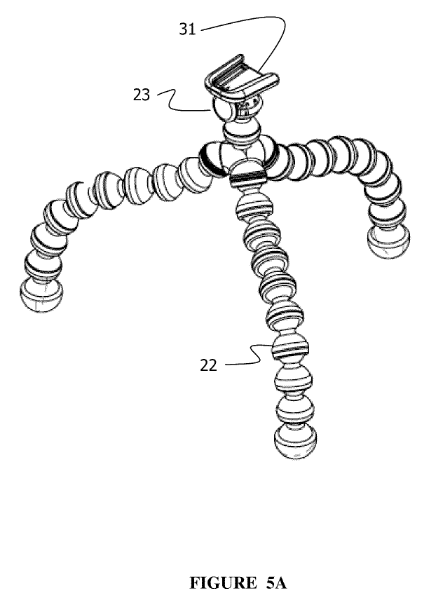

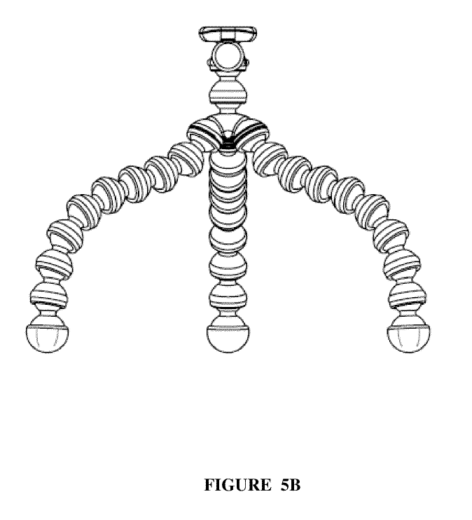

FIGS. 5A-B illustrate a flexible support structure according to some embodiments of the present invention. The tripod may have a plurality of flexible legs 22. The receiver 31 is adapted to receive a clip, which may be part of an electronic device, or may be from a mount, or other piece of apparatus.

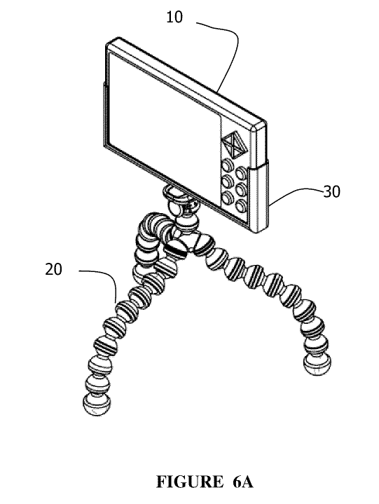

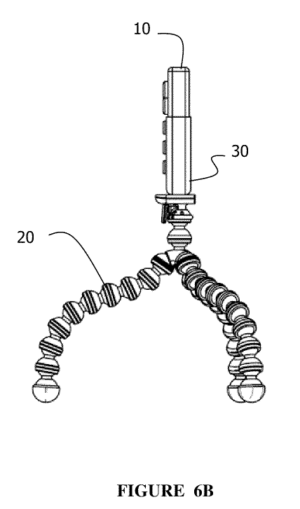

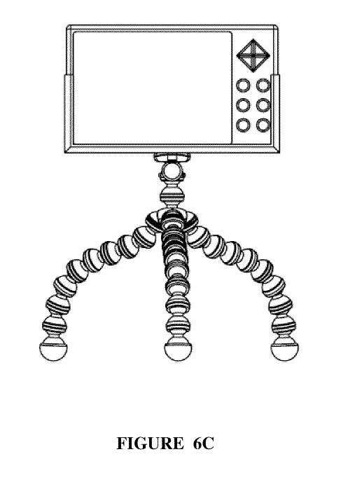

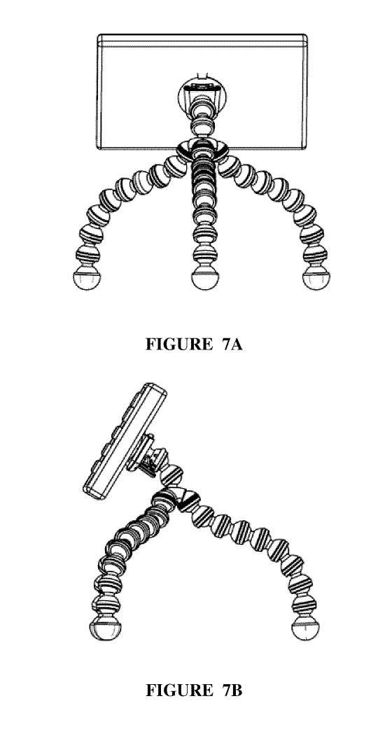

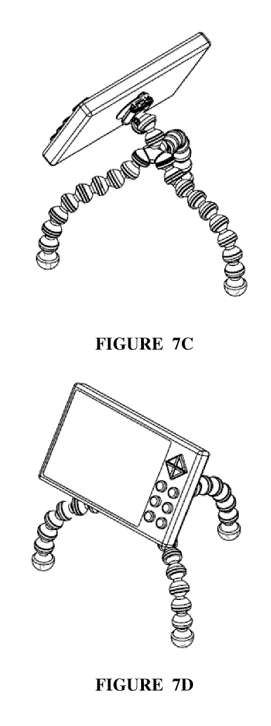

FIGS. 6A-C illustrate an apparatus assembled from an electronic device 10 mounted in a mount 30 attached to a flexible tripod 20. An apparatus such as this affords the user the convenience of using a flexible tripod as a support stand for watching video on a personal player, for example, and the use of the device mount allows the user to custom tailor their system using a mount that is designed for the player being viewed. FIGS. 7A-D illustrate an apparatus assembled from an electronic device with an integral clip mounted onto a flexible tripod according to some embodiments of the present invention.

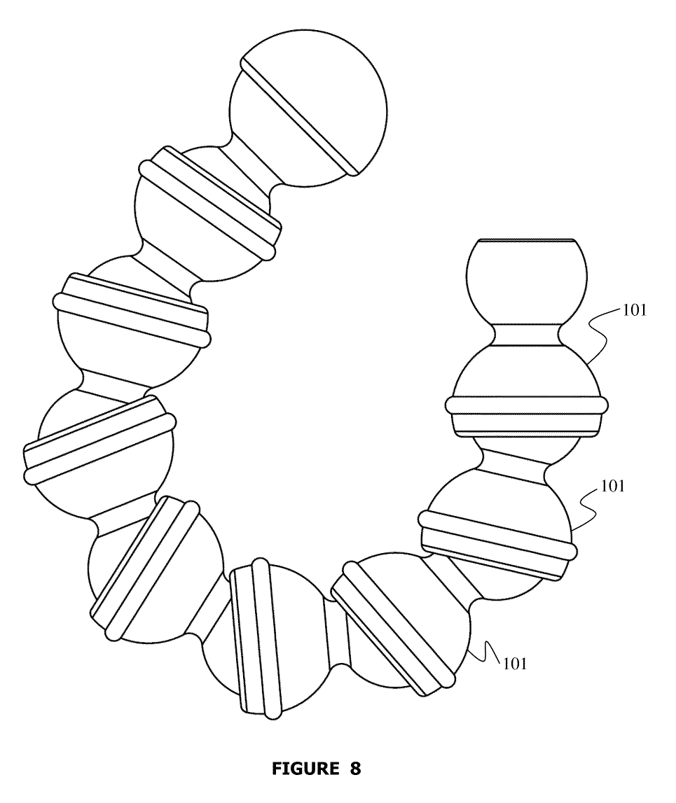

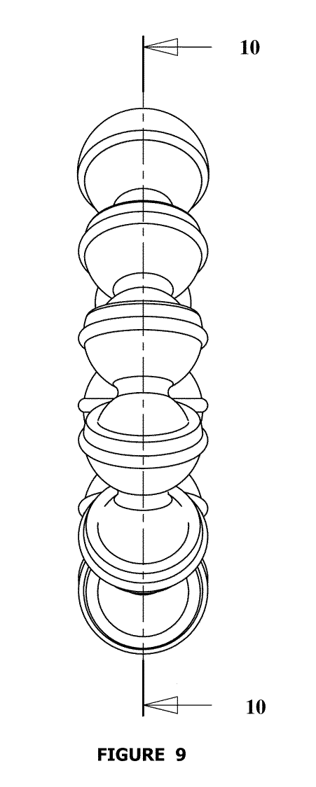

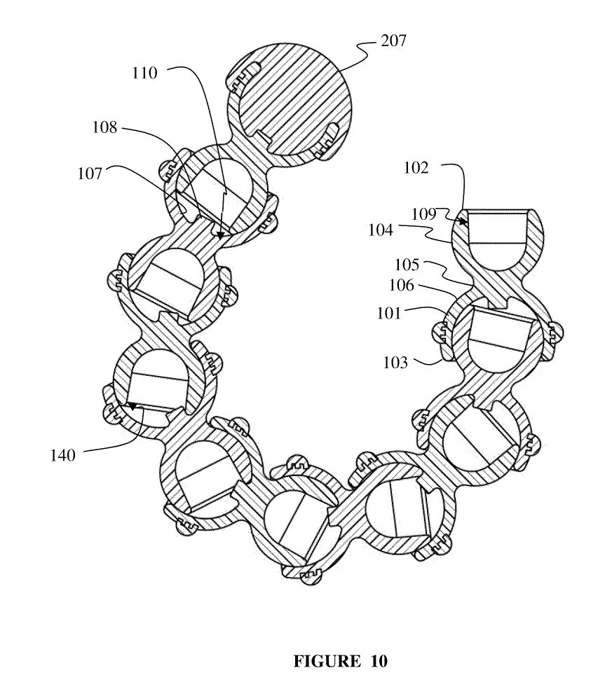

FIGS. 8, 9, and 10 illustrate a plurality of ball and socket joint connectors 101 according to some embodiments of the present invention. A connector 101 has a first end portion 102 and a second end portion 103. A socket engaging end surface 104 is present at the first end 102. The first end portion 102 is substantially hollowed out. At the end of the chain of connectors, a gripping pod 207 may be present.

The second end portion 103 has a body 106 with an internal socket receiving cavity 107. The inner surface 110 of the an internal socket receiving cavity 107 is adapted to fit over the socket engaging end surface 104 of another connector 101, or of another piece with a similar socket engaging end surface. A neckdown 105 separates the first end portion 102 from the second end portion 103. A stop nub 108 acts as a mechanical stop to prevent over angulation and possible unintentional separation of a ball and socket joint connector pair.

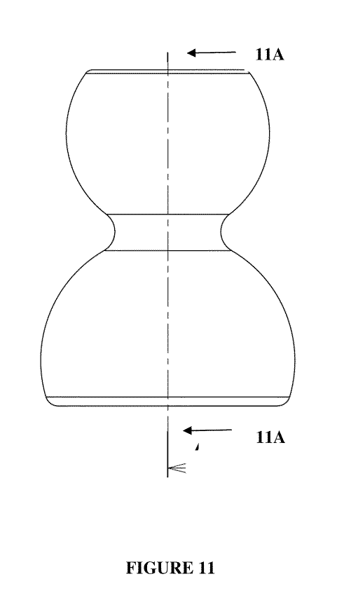

As seen in FIGS. 11 and 11A, the connector 101 has a primary axis 111 in some embodiments. The connector 101 may be symmetric around the primary axis 111 in some embodiments. The end surface planes of the first and second end portions of the connector may be perpendicular to the primary axis 111 in some embodiments.

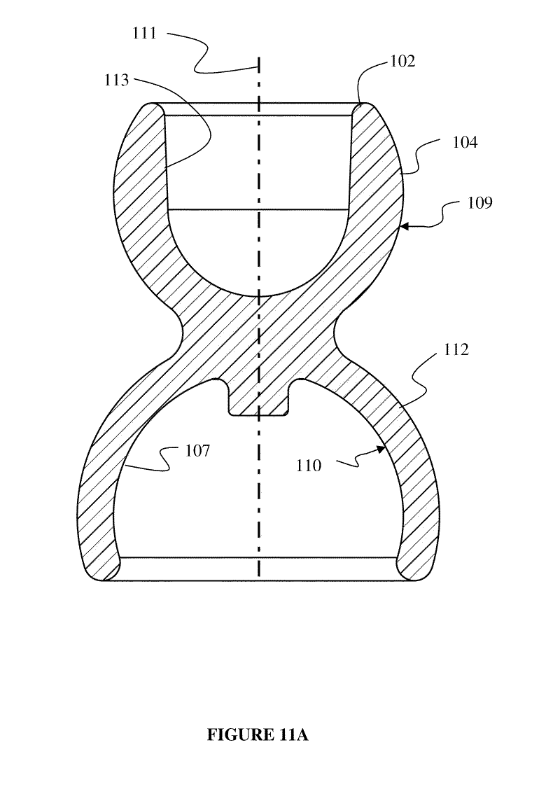

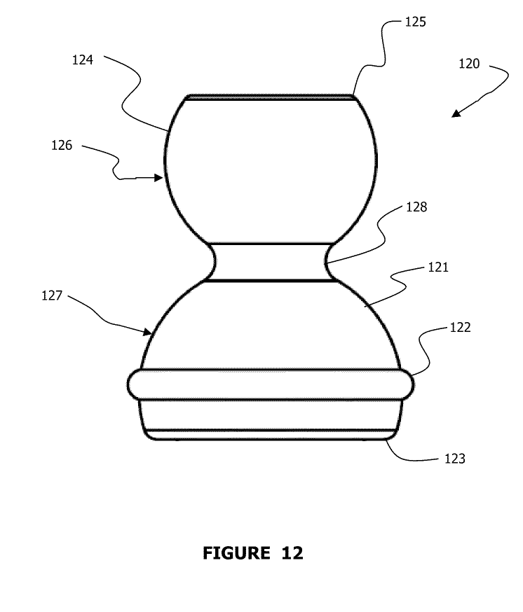

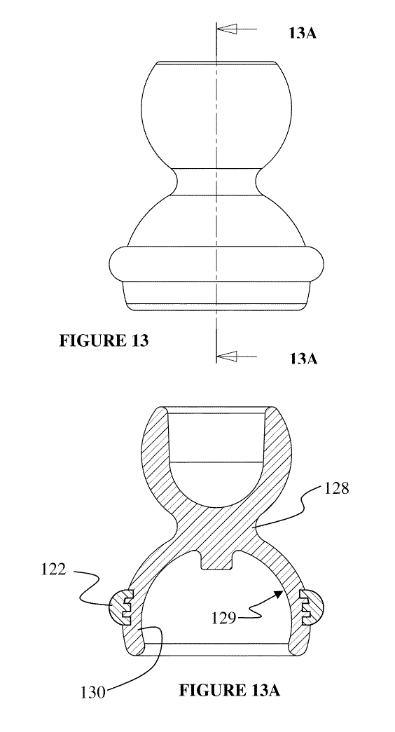

In some embodiments, as seen in FIGS. 12, 13 and 13A, a connector 120 includes a gripping portion 122. The connector 120 has a first end portion 125 and a second end portion 123. A socket engaging end surface 124 is present at the first end 125. The first end portion 125 is substantially hollowed out.

The second end 123 has a body 121 with an internal socket receiving cavity 130. The inner surface 129 of the an internal socket receiving cavity 130 is adapted to fit over the socket engaging end surface 124 of another connector, or of another piece with a similar socket engaging end surface. A neckdown 128 separates the first end portion 125 from the second end portion 123. A gripping portion 122 allows the connector to grip surfaces more readily. In some embodiments, the gripping portion is co-molded into the connector body. In some embodiments, the gripping portion is a rubberized compound. In some embodiments, the gripping portion is a circumferential ring molded into the outer surface of the connector. The gripping portion may provide a higher friction interface when the connector is set upon or wrapped around an object.

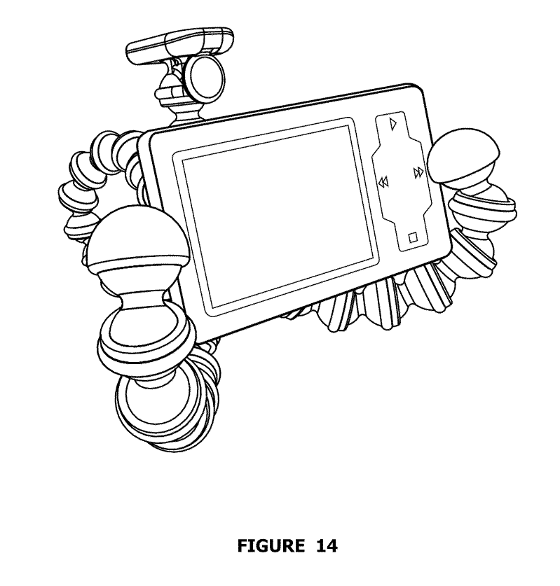

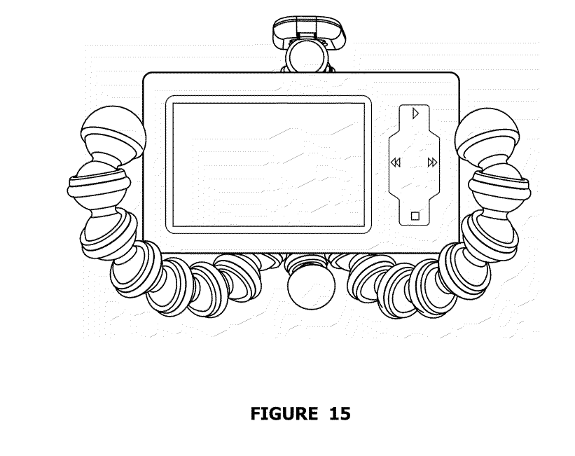

FIGS. 14 and 15 illustrate the use of a flexible tripod used to hold and position a video player in a position that allows a user to view the device.

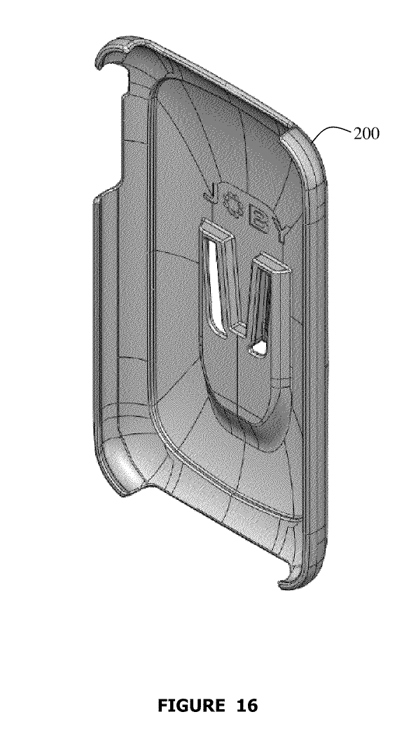

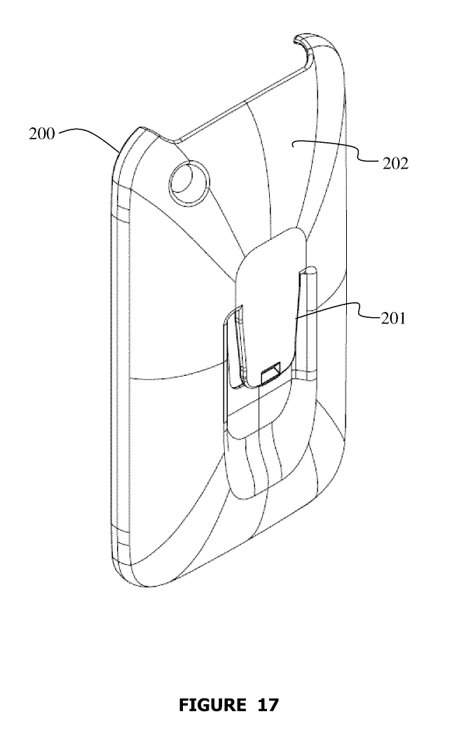

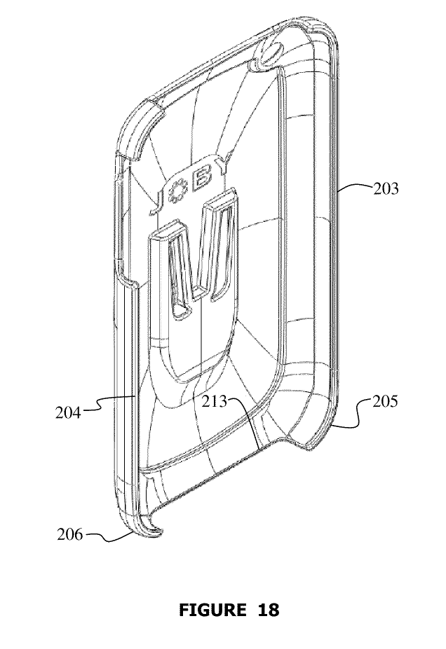

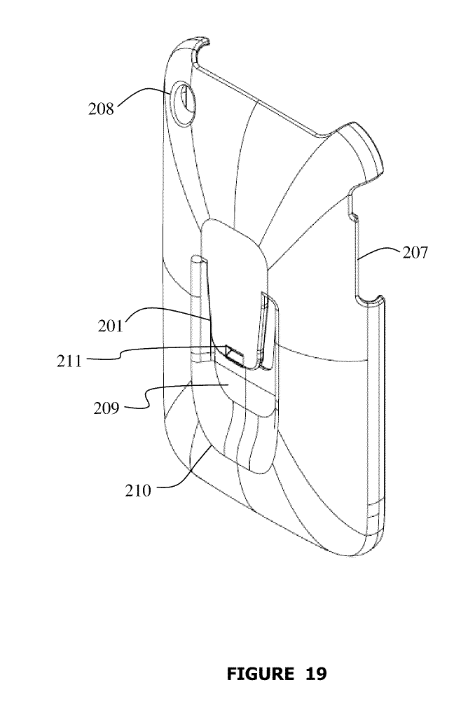

In some embodiments of the present invention, as seen in FIGS. 16, 17, 18, and 19, a case 200 is adapted to receive and hold an electronic device, such as a cellular telephone. The case 200 may have a main body 202 and a clip 201. The clip 201 is adapted to clip into a clip receiver on a support structure such as a tripod, monopod, or other support structure. The main body 202 of the case 200 is adapted to receive and hold a device such as an electronic communications device.

In some embodiments, the case 200 has sides 203, 204 which are adapted to wrap around an electronic device. The sides 203, 204 may have a lip which is adapted to capture the electronic device. The case 200 and sides 203, 204 may be elastic enough such that the sides 203, 204 may be slightly spread open as the electronic device is inserted, and then the lips of the sides reside over the top edge of the electronic device and capture the device therein. The corners 205, 206 may also have lips which are adapted to capture an inserted electronic device.

The case 200 is adapted to provide protection to the electronic device, as well as being able to allow for the attachment of the electronic device to a support structure such as a flexible tripod. Although the case provides functionality as a clip for the device to the support structure, the case may also be used at all times as a protective case. The case 200 may have cutouts 207, 212, 213, 208 adapted to allow access to ports or other features of the electronic device such that the interfaces of the electronic device while the device is mounted within the case 200. In some embodiments, the case 200 may be of ABS material. In some embodiments, the case 200 may be of polycarbonate plastic.

The rear of the main body 202 has a clip 201 adapted to clip in the mating receiver of a support structure such as a tripod. The clip 201 may reside in a well 209 within back of the main body 202 of the clip 200. The front 210 of the well 209 is adapted to allow sufficient clearance for the clip to be clipped into a mating receiver.

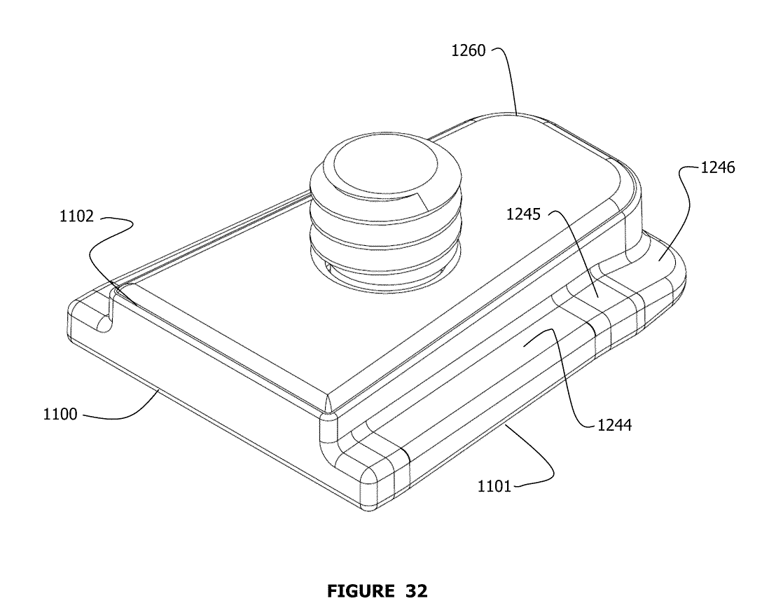

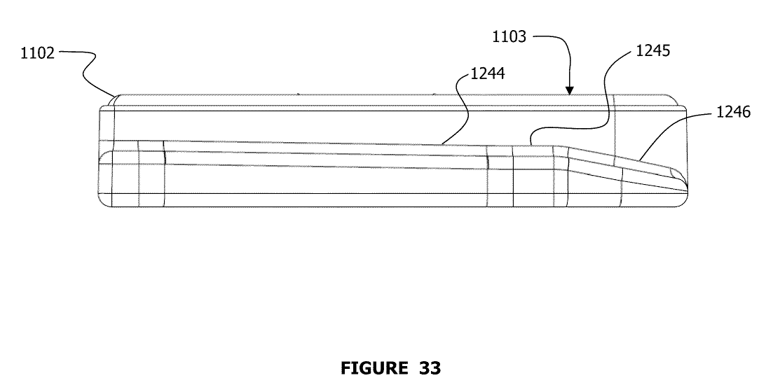

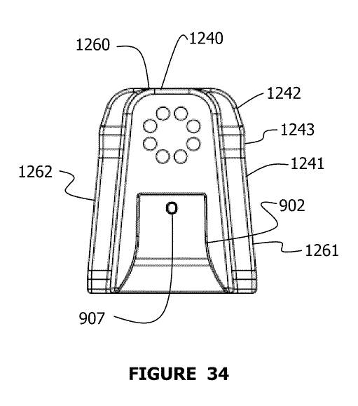

In some embodiments of the present invention, as seen in FIGS. 32, 33, and 34 in related clip types in other embodiments, the clip and its rails may have geometries adapted to allow for a good fit to a mating receiver. The mating receive may have reciprocal geometries, and the fit achieved with these reciprocal geometries may be more stable, tighter, and provide for better function of the item being supported by the clip and the supporting structure to which the clipped is attached. For example, a stable connecting interface may be sought after in the case where the clip is attached to a camera, and a more stable connection between the clip and the support structure may work to reduce jitter in the camera.

A clip according to embodiments of this invention may have variations in the width of the clip, as well as variations in the height (thickness) of the rail around the main flat plate of the clip. The clip has a main body consisting at least in part of a plate 1260, the flat plate having rails 1261, 1262 around its periphery. The width of the clip, which in some embodiments will be defined as the distance between the outer edges of the two rails on opposing sides of the plate, may vary along the length of the clip. In some embodiments the clip may have a first neckdown portion 1241 which narrows the clip width along the direction towards the insertion end of the clip, that is to say, the end of the clip adapted to be inserted into a mating receiver. Closer to the insertion end of the clip, there may be a second neckdown portion 1242. In some embodiments, the angle of the neckdown may be different in the second neckdown portion 1242 than the angle of the neckdown in the first neckdown portion 1241. In some embodiments, the angle of the neckdown in the second neckdown portion 1242 may be steeper than the angle of the neckdown in the first neckdown portion 1241. The steeper neckdown in the second neckdown portion 1242 may be useful in allowing for easier insertion of the clip into a mating receiver, as the narrower portion need not be as closely aligned as one attempts to clip the clip into the receiver, gradual widening of the clip may allow for self-alignment of the clip in the receiver as the clip is further inserted into the receiver.

In some embodiments, there may be an intermediate portion 1243 of the clip wherein the width of the clip does not change. The variation of the clip width in this fashion may allow for both easier insertion of the clip into a receiver, and also provide for firmer, more stable attachment of the clip into the receiver. In some embodiments, a clip as described above may be a clip adapted to be attached to another device, such as a camera, light, flash unit, video player, or other device. In some embodiments, a clip as described above may be part of another device, such as a camera, light, flash unit, video player, or other device.

The height (thickness) of the clip rails may vary along the length of the rail. In some embodiments, the rail height may lower along one or more areas of the length of the rail at different rates of change. In some embodiments, both the width of the clip and the height of the clip rail may vary along the length of the rail. In some embodiments, the rail may decrease in thickness along a first portion 1244 at a first rate. The rail thickness may decrease in thickness along a second portion 1246, at the same or a different rate. There may be an intermediate portion 1245 which may not have a change of thickness.

In some embodiments, the first portion 1244 of the height change of the rail may coincide with the first neckdown portion 1141, the intermediate portion 1245 of the rail height may coincide with the intermediate portion 1243 of the rail width, and the second portion 1246 of the rail height may coincide with the with the second neckdown portion 1242 of the rail width. In some embodiments, the clip may be adapted to clip into a receiver with reciprocal geometries with regard to the rails. In some embodiments, the clip may not be adapted to be an intermediate bridge to another device but instead may be part of another device, such as a camera, light, flash unit, video player, or other device.

In some or all of the embodiments of the clip, the clip may have recess 211 on its bottom surface adapted to be filled by a tab on a spring loaded lever that is part of the mating receiver.

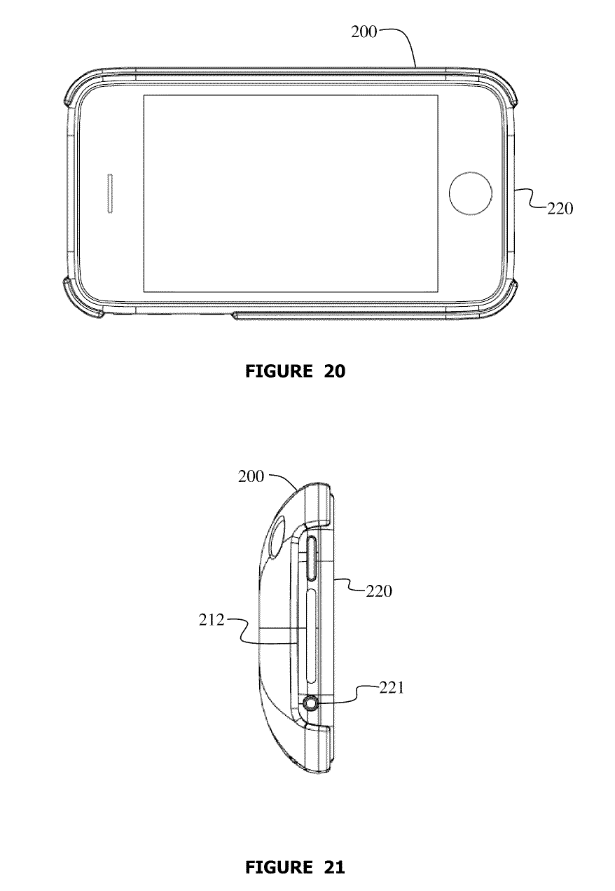

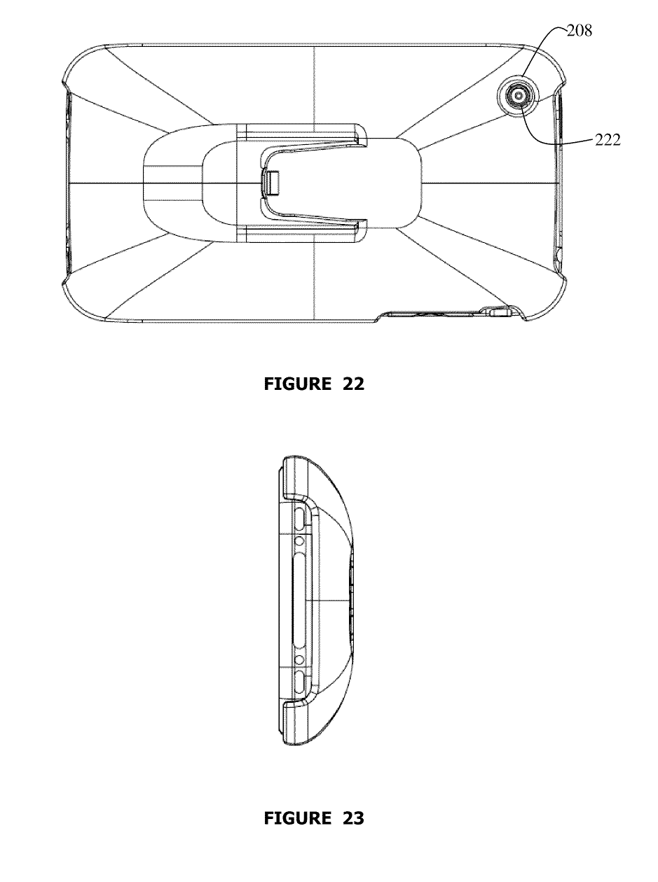

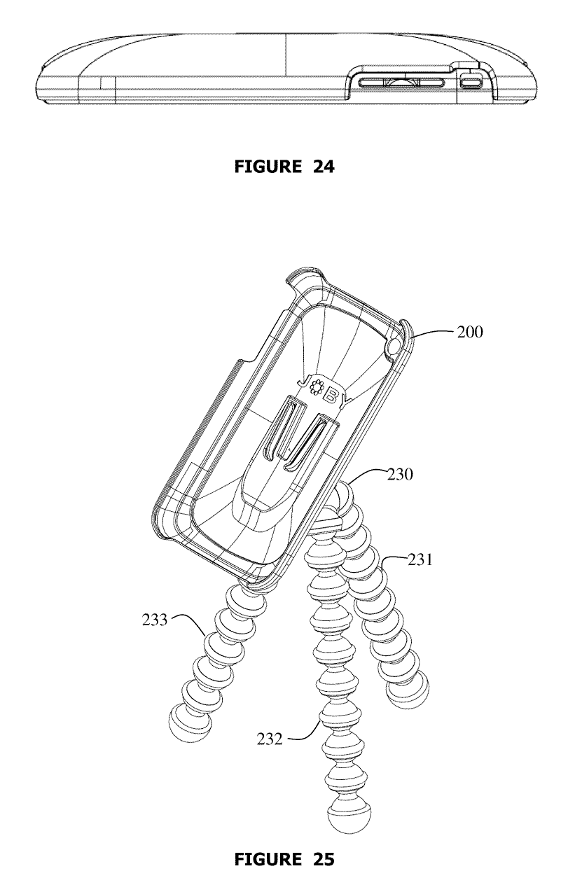

In some embodiments of the present invention, as seen in FIGS. 20-24, a case 200 is adapted to receive and hold an electronic device 220, which may be a cellular telephone. The rim of the case 200 is adapted to capture the electronic device 220. Functional interfaces or other operational aspects 222, 221 of the electronic device 220 are located within cutouts 212, 208 in the case such that the electronic device 220 may be fully operated while in the case 200. The case 200 provides a clip interface to a support structure, when desired, and also provides protection to the electronic device 220.

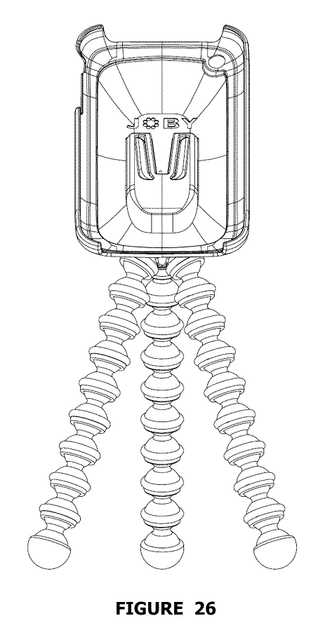

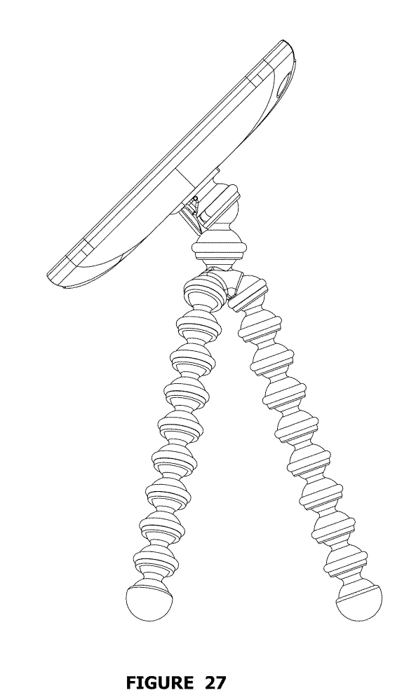

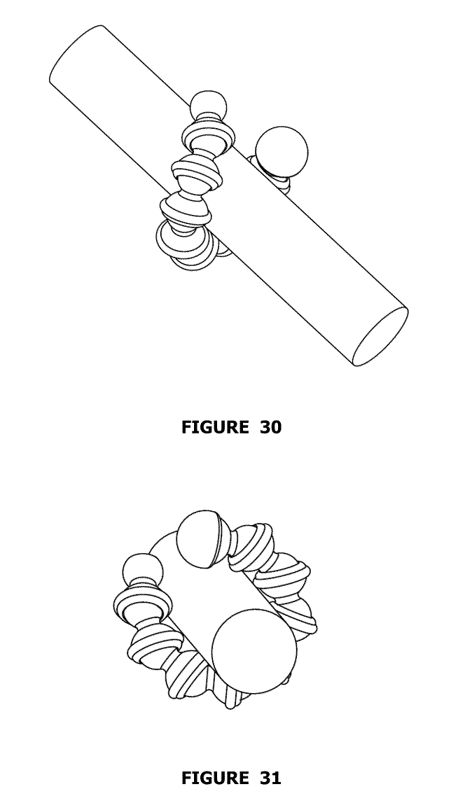

FIGS. 25-27 illustrate the clip 200 clipped into a tripod 230 according to some embodiments of the present invention. The tripod 230 may have flexible legs 231, 232, 233 which are also adapted to wrap around items in order to allow the positioning of the mounted items on the tripod in a variety of places. FIGS. 30 and 31 illustrate aspects of the flexibility of the legs and the use of the gripping portions of the legs when wrapped around an object.

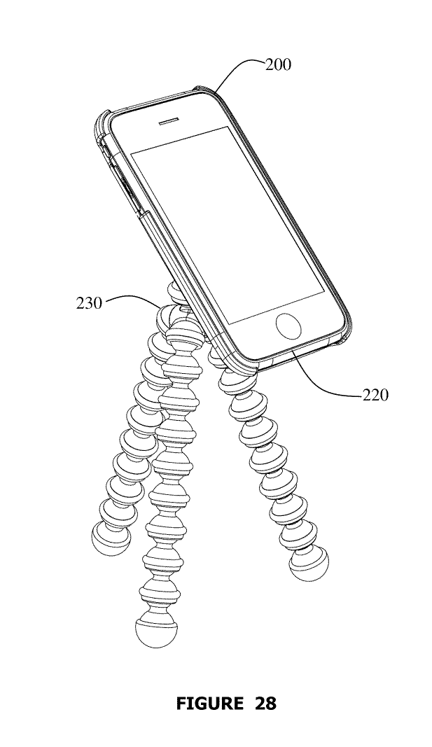

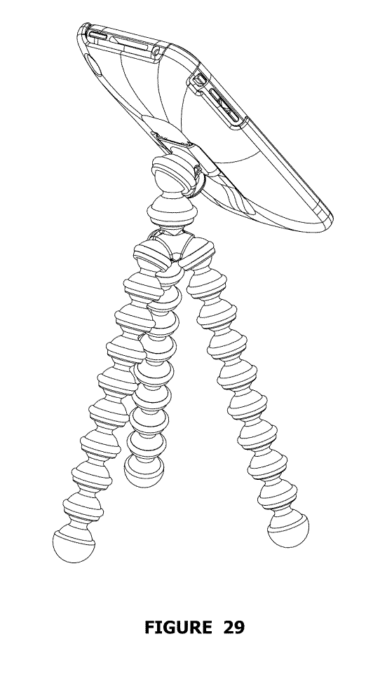

In some embodiments of the present invention, an apparatus for the holding of an electronic device is seen in FIGS. 28 and 29. An electronic device 220 is held in a case 200 and attached to a flexible tripod 230.

As evident from the above description, a wide variety of embodiments may be configured from the description given herein and additional advantages and modifications will readily occur to those skilled in the art. The invention in its broader aspects is, therefore, not limited to the specific details and illustrative examples shown and described. Accordingly, departures from such details may be made without departing from the spirit or scope of the applicant's general invention.

I claim:

1. A case assembly for an electronic device, said case assembly comprising:
a device case, said device case comprising:
a main body, said main body adapted to receive an electronic device, said main body comprising a rear floor; and
a clip, said clip attached to the rear floor of said main body, said clip adapted to clip into a mating receiver.

2. The case assembly of claim 1 wherein said main body further comprises:
a plurality of edge portions around said rear floor of said main body, said edge portions attached to said rear floor of said main body, wherein said edge portions combine with said rear floor to form a receptacle area for an object.

3. The case assembly of claim 2 wherein said edge portions comprise a lip curved towards said receptacle area, said lip adapted to capture said object.

4. The case assembly of claim 2 wherein said receptacle area is substantially rectangular.

5. The case assembly of claim 3 wherein said receptacle area is substantially rectangular.

6. The case assembly of claim 4 wherein the substantially rectangular receptacle area comprises rounded corners.

7. The case assembly of claim 2 further comprising a flexible tripod, said tripod comprising:
a body portion;
a clip receiver connected to said body portion, said clip receiver adapted to receive the clip attached to the main body of the device case; and
a plurality of flexible legs, said flexible legs comprising a first end and a second end, said first end connected to said body portion

8. The case assembly of claim 7 wherein each of said plurality of flexible legs comprises a plurality of interconnected connectors, said connectors comprising:
a connector body, said connector body comprising:
a first end portion;
a second end portion;
a socket engaging surface at said first end portion, said socket engaging surface being the external surface at said first end portion; and
an internal socket receiving cavity at said second end portion.

9. The case assembly of claim 8 wherein said connectors further comprise a gripping portion, said gripping portion located around the outer periphery of said second end portion.

10. The case assembly of claim 9 wherein said clip receiver comprises a spring loaded tab adapted to capture said clip.

11. The case assembly of claim 10 wherein said clip comprises a recess in its bottom surface, said recess adapted to fit said spring loaded tab when said clip is attached to said clip receiver.

12. The case assembly of claim 10 further comprising an electronic device, said electronic device mounted into said device case.

13. The case assembly of claim 3 further comprising a flexible tripod, said tripod comprising:
a body portion;
a clip receiver connected to said body portion, said clip receiver adapted to receive the clip attached to the main body of the device case; and
a plurality of flexible legs, said flexible legs comprising a first end and a second end, said first end connected to said body portion

14. The case assembly of claim 13 wherein each of said plurality of flexible legs comprises a plurality of connectors, said connectors comprising:
a connector body, said connector body comprising:
a first end portion;
a second end portion;
a socket engaging surface at said first end portion, said socket engaging surface being the external surface at said first end portion; and
an internal socket receiving cavity at said second end portion.

15. The case assembly of claim 14 wherein said connectors further comprise a gripping portion, said gripping portion located around the outer periphery of said second end portion.

16. The case assembly of claim 15 wherein said clip receiver comprises a spring loaded tab adapted to capture said clip.

17. The case assembly of claim 16 wherein said clip comprises a recess in its bottom surface, said recess adapted to fit said spring loaded tab when said clip is attached to said clip receiver.

18. The case assembly of claim 17 further comprising an electronic device, said electronic device mounted into said device case.
